(19) United States
(12) Patent Application Publication
(10) Pub. No.: US 2011/0318894 A1
(43) Pub. Date: Dec. 29, 2011

(54) METHOD FOR MANUFACTURING SEMICONDUCTOR DEVICE

(75) Inventors: Hitoshi Kobayashi, Ishikawa-ken (JP); Shinya Ikesaka, Saitama-ken (JP)

(73) Assignee: KABUSHIKI KAISHA TOSHIBA, Tokyo (JP)

(21) Appl. No.: 13/053,511

(22) Filed: Mar. 22, 2011

(30) Foreign Application Priority Data
Jun. 23, 2010 (JP) 2010-142757

(51) Int. Cl. H01L 21/336

(52) U.S. Cl. 438/270; 257/E21.41

(57) ABSTRACT

According to one embodiment, a method is disclosed for manufacturing a semiconductor device. The method can include forming a first semiconductor region of a second conductivity type on a semiconductor layer of a first conductivity type, forming a mask selectively opening a surface of the first semiconductor region, and forming a trench penetrating through the first semiconductor region to reach the semiconductor layer. The method can include exposing further a part of the surface of the first semiconductor region from the mask. The method can include forming a control electrode in the trench, and forming selectively a second semiconductor region of the first conductivity type on the surface of the first semiconductor region. The method can include removing the mask having the opening. The method can include forming selectively a third conductor region of the second conductivity type on the surface of the first semiconductor region.

### CROSS-REFERENCE TO RELATED APPLICATIONS

This application is based upon and claims the benefit of priority from the prior Japanese Patent Application No. 2010-142757, filed on Jun. 23, 2010; the entire contents of which are incorporated herein by reference.

### FIELD

Embodiments described herein relate generally to a method for manufacturing a semiconductor device.

### BACKGROUND

Regarding semiconductor device such as Metal Oxide Semiconductor Field Effect Transistor (MOSFET) with upper/lower electrode structure, there is a known technology for forming a trench penetrating through a base region and for forming a gate electrode in the trench in order to reduce the cell area and reduce the ON-resistance.

In contrast, to improve the resistance to avalanche breakdown in such a semiconductor device, there has also been developed a technology for forming a trench-contact layer reaching the base region. The trench-contact layer is electrically connected to, for example, a source electrode of MOSFET. With the structure, a carrier generated in a semiconductor device can be efficiently discharged to the source electrode via the trench-contact layer, which improves the resistance to avalanche breakdown of the semiconductor device.

However, as the cell-pitch in the semiconductor device becomes finer, there raises a request of forming the trench-contact layer so as not to affect the threshold voltage (Vth) of MOSFET. Therefore, the manufacturing process of forming the trench-contact layer becomes further complex, which raises a problem of increasing the manufacturing cost of semiconductor device.

On the other hand, there has been developed a technology of forming a carrier-free region in the base region, not forming the trench-contact layer, to efficiently discharge the carrier generated in the semiconductor device. As the cell-pitch in the semiconductor becomes finer, however, the technology raises a problem of troublesome technique of positioning the carrier-free region in the base region, thus increases the manufacturing cost of semiconductor device.

Accordingly, the miniaturization of cell-pitch in semiconductor device and the reduction of manufacturing cost are in an opposing relationship to each other.

### BRIEF DESCRIPTION OF THE DRAWINGS

FIGS. 1A and 1B are schematic cross-sectional views of a semiconductor device according to a first embodiment;

FIGS. 2A to 2C are schematic cross-sectional views describing a manufacturing process of the semiconductor device according to the first embodiment;

FIGS. 3A to 3C are schematic cross-sectional views describing a manufacturing process of the semiconductor device according to the first embodiment;

FIGS. 4A to 4C are schematic cross-sectional views describing a manufacturing process of the semiconductor device according to the first embodiment;

FIGS. 5A and 5B are schematic cross-sectional views describing a manufacturing process of the semiconductor device according to the first embodiment;

FIG. 6 is a schematic cross-sectional view of a semiconductor device according to a first comparative example;

FIG. 7 is a schematic cross-sectional view of a semiconductor device according to a second comparative example;

FIG. 8 is a schematic cross-sectional view of a semiconductor device according to a second embodiment;

FIGS. 9A to 9C are schematic cross-sectional views describing a manufacturing process of the semiconductor device according to the second embodiment;

FIGS. 10A to 10C are schematic cross-sectional views describing a manufacturing process of the semiconductor device according to the second embodiment;

FIG. 11 is a schematic cross-sectional view of a semiconductor device according to a third embodiment;

FIGS. 12A to 12C are schematic cross-sectional views describing a manufacturing process of the semiconductor device according to the third embodiment;

FIGS. 13A to 13C are schematic cross-sectional views describing a manufacturing process of the semiconductor device according to the third embodiment;

FIGS. 14A to 14C are schematic cross-sectional views describing a manufacturing process of the semiconductor device according to the third embodiment;

FIGS. 15A and 15B are schematic cross-sectional views describing a manufacturing process of the semiconductor device according to the third embodiment; and

FIG. 16 is a schematic cross-sectional view of a semiconductor device according to a third comparative example.

### DETAILED DESCRIPTION

In general, according to one embodiment, a method is disclosed for manufacturing a semiconductor device. The method can include forming a first semiconductor region of a second conductivity type on a semiconductor layer of a first conductivity type. The method can include forming a mask selectively opening a surface of the first semiconductor region. The method can include forming a trench penetrating through the first semiconductor region to reach the semiconductor layer by etching the first conductor region exposed at an opening of the mask. The method can include further exposing a part of the surface of the first semiconductor region from the mask by enlarging the opening of the mask. The method can include forming a control electrode in the trench via a first insulating film. The method can include selectively forming a second semiconductor region of the first conductivity type on the surface of the first semiconductor region by selectively shielding the first semiconductor region through the mask and by injecting impurity of the first conductivity type into the part of the first semiconductor region. The method can include removing the mask having the opening. In addition, the method can include selectively forming a third conductor region of the second conductivity type, having a higher concentration of impurity than a concentration of impurity in the first semiconductor region, on the surface of the first semiconductor region by injecting impurity of the second conductivity type into the first semiconductor region other than a portion in which the second semiconductor region is formed.

Various embodiments will be described hereinafter with reference to the accompanying drawings.

### First Embodiment

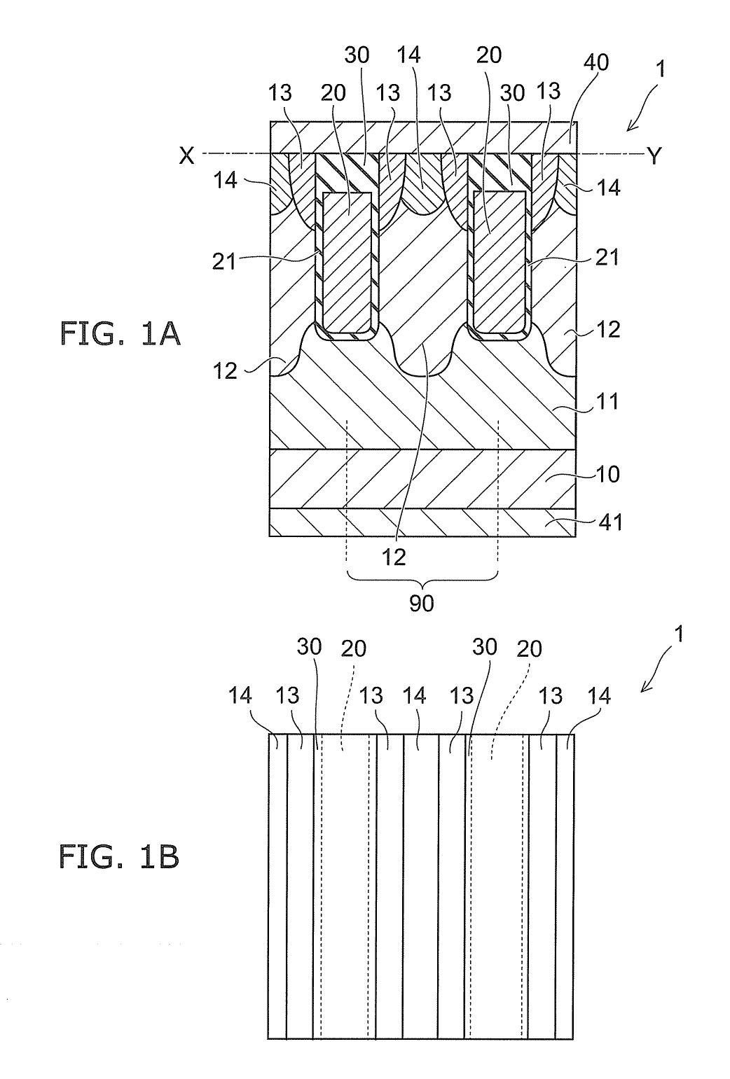

FIGS. 1A and 1B are schematic cross-sectional views of a semiconductor device according to a first embodiment. FIG. 1A illustrates a schematic cross-sectional view of the semiconductor device, and FIG. 1B illustrates a schematic upper surface view of section X-Y in FIG. 1A viewed from above.

A semiconductor device 1 illustrated in FIGS. 1A and 1B are a vertical trench-gate type MOSFET.

As illustrated in FIG. 1A, the semiconductor device 1 includes a semiconductor layer 11 that is a drift layer on a semiconductor substrate 10. The conductivity type of the semiconductor substrate 10 is, for example, n⁺-type, and the conductivity type of the semiconductor layer 11 is, for example, n⁻-type. A base region (a first semiconductor region) 12 is provided on the semiconductor layer 11. The conductivity type of the base region 12 is, for example, p-type. On the surface of the base region 12, a source region (a second semiconductor region) 13 is selectively provided. The conductivity type of the source region is, for example, n⁺-type. Other than these, a contact region (a third semiconductor region) 14 is selectively provided on the surface of the base region 12. The contact region 14 functions as a carrier-free region. The contact region 14 is contact with the source region 13. The conductivity type of the contact region 14 is, for example, p⁺-type. The drain region of MOSFET is made of, for example, the semiconductor substrate 10 and the semiconductor layer 11.

In the semiconductor device 1, a gate electrode (a control electrode) 20 is provided so as to penetrate through the base region 12 from the source region 13 toward the semiconductor layer 11. That is, the gate electrode 20 becomes a vertical trench gate. The upper end of the gate electrode is provided at higher level than the lower end of the source region 13, and the lower end of the gate electrode 20 reaches the semiconductor layer 11 provided beneath the base region 12. A gate insulating film (a first insulating film) 21 is interposed between the gate electrode 20 and each of the semiconductor layer 11, the base region 12, and the source region 13. On the gate electrode 20 and the gate insulating film 21, an interlayer insulating film 30 is provided.

In the semiconductor device 1, a source electrode 40 is provided on the source region 13, the contact region 14, and the interlayer insulating film 30. The source electrode 40 is electrically connected to the source region 13 and the contact region 14. A drain electrode 41 is provided beneath the semiconductor substrate 10. The drain electrode 41 is electrically connected to the semiconductor substrate 10.

On the plane of the semiconductor device 1 illustrated in FIG. 1B, there are arranged the source region 13, the contact region 14, and the gate electrode 20 in a stripe pattern. The source region 13, the contact region 14, and the gate electrode 20 are disposed in parallel with each other.

Distance between the centers of adjacent gate electrodes 20, (the distance of a region represented by a numeral 90) is, for example, 1.0 μm or smaller. The distance corresponds to the cell-pitch in the semiconductor device 1. In the semiconductor device 1, the unit cells provided in the cell region 90 are repeatedly arranged in the direction almost parallel to the major surface of the semiconductor substrate 10. The width of the base region 12 between adjacent gate electrodes 20 is, for example, 0.5 μm or smaller. Meanwhile, in the first embodiment, the term “width” signifies the length of each member in the direction of cell-pitch arrangement, for example.

The main component of the semiconductor substrate 10, the semiconductor layer 11, the base region 12, the source region 13, and the contact region 14 is, for example, silicon (Si). The semiconductor layer 11 and the source region 13 contain n-type impurities. The base region 12 and the contact region 14 contain p-type impurities. The material of the gate electrode 20 is, for example, a polysilicon. The material of the gate insulating film 21 is, for example, silicon oxide (SiO₂). The material of the interlayer insulating film 30 is, for example, silicon oxide (SiO₂). The material of the source electrode 40 and the drain electrode 41 is, for example, a conductive metal. The conductive metal includes pure metal, alloy, and conductive metal compound. The pure metal includes aluminum (Al) and tungsten (W).

When a certain voltage is applied between the source electrode 40 and the drain electrode 41 in that type of semiconductor device 1, (for example, ground potential to the source electrode 40, and a positive potential to the drain electrode 41), and when a voltage higher than the threshold voltage is applied to the gate electrode 20, a channel (an inversion layer) is formed in the base region 12 facing the gate electrode 20 via the gate insulating film 21. And then a current flows between the source electrode 40 and the drain electrode 41 through the source region 13, the channel, the semiconductor layer 11, and the semiconductor substrate 10. That is, the semiconductor device 1 enters ON state. When the voltage of the gate electrode 20 becomes lower than the threshold voltage, no channel is formed in the base region 12, and no current flows between the source electrode 40 and the drain electrode 41. That is, the semiconductor device 1 enters OFF state.

When the semiconductor device 1 is in ON state, electronic current flows between the source region 13 and the semiconductor layer 11 via the channel. Consequently, the potential difference between the source region 13 and the semiconductor layer 11 becomes very small. In contrast, when the semiconductor device 1 is switched from ON state to OFF state, the potential difference between the source region 13 and the semiconductor layer 11 abruptly increases, and temporarily exceeds the potential difference in the OFF state to result in an over-voltage state.

At this moment, there is generated avalanche breakdown at the joint interface of the base region 12 and the semiconductor layer 11, which generates electron-hole pair in some cases.

When holes are accumulated in the semiconductor device 1, the avalanche breakdown is further accelerated to result in breakdown of the semiconductor device 1 in some cases. In the semiconductor device 1, however, the generated hole migrates in the base region 12 toward the source electrode 40, and is efficiently discharged to the source electrode 40 via the contact region 14 which is a carrier-free region. As a result, the semiconductor device 1 assures high resistance to avalanche breakdown.

The process of manufacturing the semiconductor device 1 will be described below.

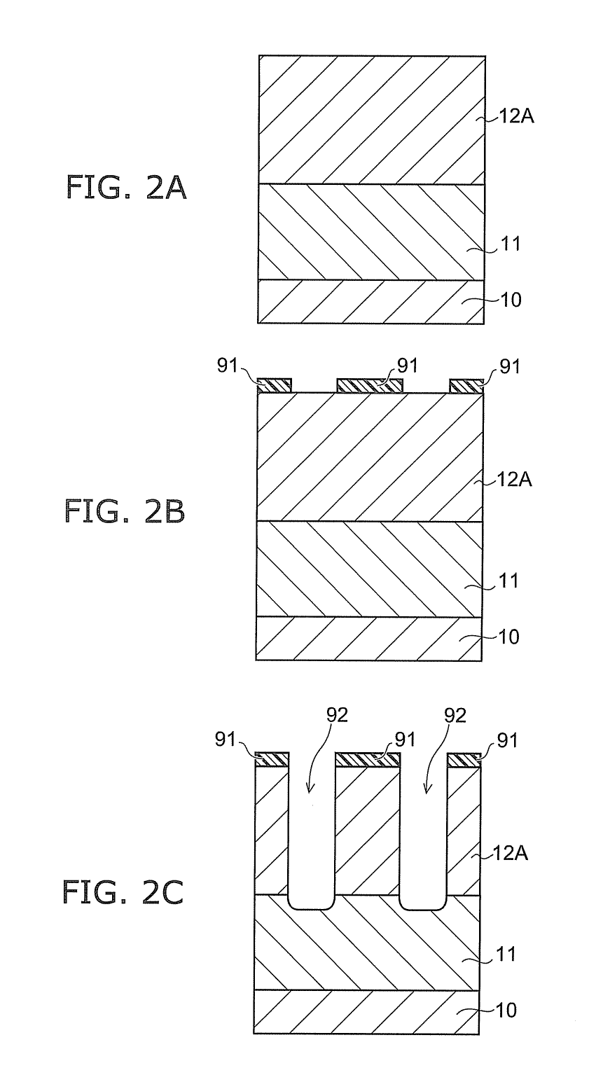

FIGS. 2A to 2C are schematic cross-sectional views describing a manufacturing process of the semiconductor device according to the first embodiment. FIG. 2A illustrates a schematic cross-sectional view for forming the base layer, FIG. 2B illustrates a schematic cross-sectional view for forming the mask for forming the trench gate, and FIG. 2C illustrates a schematic cross-sectional view for describing etching process using the mask.

As illustrated in FIG. 2A, the semiconductor layer 11 of the first conductivity type (such as n-type) is formed on the semiconductor substrate 10 by epitaxial growth method. Then, on the semiconductor layer 11, there is formed a base region 12A which is a semiconductor layer of the second conductivity type (such as p-type) by ion implantation method. For example, the base region 12A is formed on the semiconductor layer 11 by injecting p-type impurities such as boron (B) into the layer on the semiconductor layer 11. Alternatively, epitaxial growth method may be applied to form the base region 12A on the semiconductor layer 11.

As described later, the source region 13 and the contact region 14 are formed on the surface of the base region 12A in self-aligning mode. That is, the semiconductor region in which the source region 13 and the contact region 14 are removed from the base region 12A becomes the base region 12.

Then, as illustrated in FIG. 2B, there is formed a mask 91 which selectively opens the surface of the base region 12A on the base region 12A. The mask 91 is a mask for forming the trench gate, and is patterned by photolithography. The material of the mask is, for example, silicon oxide (SiO₂).

Then, as illustrated in FIG. 2C, the base region 12A exposed at the opening of the mask 91 is etched. For example, the mask 91 is used as a shielding film, and the etching process is performed on the base region 12A at a portion exposed from the mask and on the semiconductor layer 11 at a portion of the exposed base region 12A. The etching method is, for example, reactive ion etching (RIE). The etching process removes the base region 12A at portions other than the region being shielded by the mask 91 and removes the upper layer portion of the semiconductor layer 11 positioned beneath the portion of removed base region 12A. The etching process forms a trench 92 penetrating the base region 12A to reach the semiconductor layer 11.

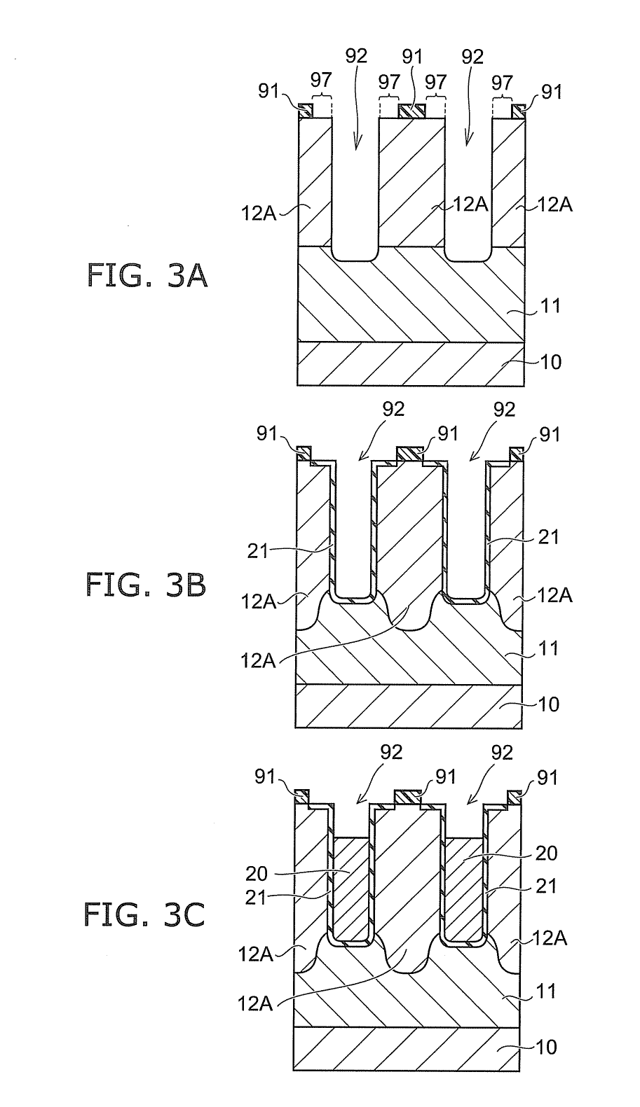

FIGS. 3A to 3C are schematic cross-sectional views describing the manufacturing process of the semiconductor device according to the first embodiment. FIG. 3A illustrates a schematic cross-sectional view describing the process for enlarging the opening of mask, FIG. 3B illustrates a schematic cross-sectional view describing the process for forming the gate insulating film, and FIG. 3C illustrates a schematic cross-sectional view describing the process for forming the gate electrode.

As illustrated in FIG. 3A, the opening of the mask 91 is enlarged to thereby expose a part of the surface of the base region 12A from the mask 91. For example, side-etching is performed on the mask 91 to thereby expose a part of the surface of the base region 12A from the mask 91. The side-etching is, for example, isotropic etching (wet etching).

The side-etching removes the side surfaces of the mask 91. For example, as illustrated in FIG. 3A, the mask 91 in a region 97 is removed. As a result, the opening width of the mask 91 becomes larger than that before forming the trench 92. Adjustment of the opening width of the mask 91 is carried out by, for example, controlling the time of isotropic etching. By the removal of the side surfaces of the mask 91, the surface of the base region 12A is exposed at the region 97.

Then, as illustrated in FIG. 3B, the gate insulating film 21 is formed on inside wall of the trench 92. For example, the semiconductor layer 11 and the base region 12A are heated in an oxidizing gas atmosphere such as oxygen (O₂). That is, the gate insulating film 21 is formed on inside wall of the trench 92 by thermal oxidation. Furthermore, the heating causes the impurities in the base region 12A to diffuse toward the semiconductor layer 11, thus making a part of the boundary between the semiconductor layer 11 and the base region 12A move toward the semiconductor substrate 10. During the process, however, a state is maintained in which the trench 92 penetrates the base region 12A to reach the semiconductor layer 11.

Regarding the gate insulating film 21, the first embodiment includes the formation thereof by chemical vapor deposition (CVD) other than the formation thereof by thermal oxidation.

Then, as illustrated in FIG. 3C, the gate electrode 20 is formed in the trench 92 via the gate insulating film 21. The gate electrode 20 is formed by, for example, a CVD method. As for the gate electrode 20, etch-back is applied thereto to adjust the height of the upper surface thereof, and thus to adjust the upper surface thereof so as to become higher than the lower end of the source region 13 to be formed in succeeding process.

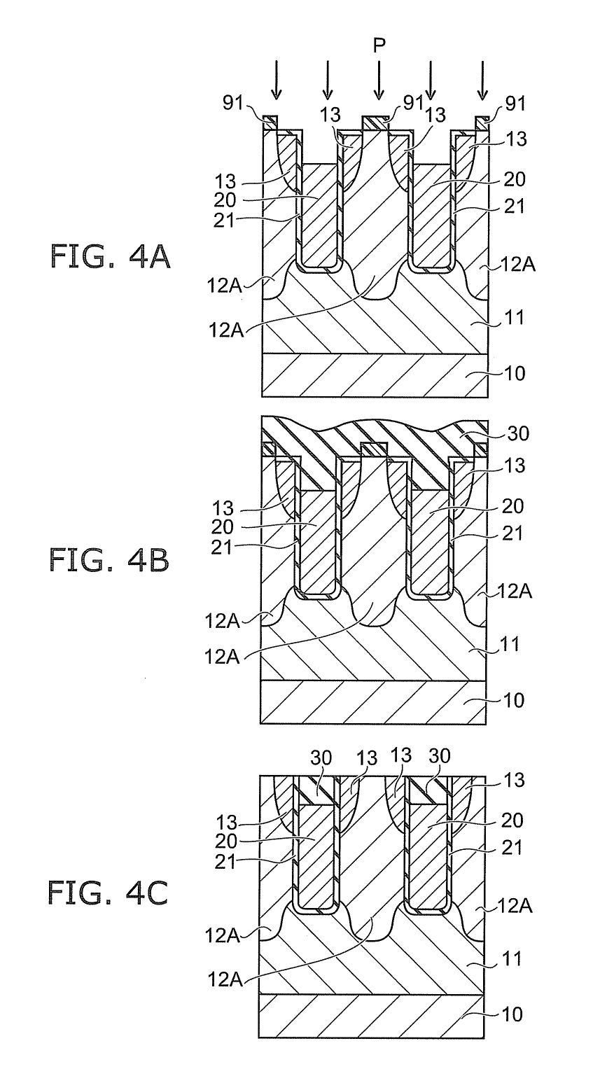

FIGS. 4A to 4C are schematic cross-sectional views describing the manufacturing process of the semiconductor device according to the first embodiment. FIG. 4A illustrates a schematic cross-sectional view in the process for forming the source region, FIG. 4B illustrates a schematic cross-sectional view in the process for forming the interlayer insulating film, and FIG. 4C illustrates a schematic cross-sectional view in the process for removing the interlayer insulating film and the mask.

As illustrated in FIG. 4A, the mask 91 with enlarged opening is used as the shielding film, and impurities of first conductivity type (n-type) are injected into a part of the base region 12A. For example, n-type impurities such as phosphorus (P) are injected into a part of the base region 12A and into the exposed surface of the gate electrode 20. The direction of injecting the n-type impurities is almost normal to the major surface of the semiconductor substrate 10.

During the operation, the n-type impurities are not injected into the base region 12A covered with the mask 91, and is injected into the base region 12A exposed from the mask 91. The condition of ion implantation is adjusted to the extent that the n-type impurities pass through the gate insulating film 21 formed on the base region 12A. Furthermore, into the upper layer of the base region 12A exposed from the mask 91, the n-type impurities are injected to the extent that the conductivity type of the base region 12A is reversed.

The operation selectively forms the n-type source region 13 on the surface of the base region 12A. The source region 13 is formed in a range from the upper end edge of the base region 12A to the midstream of the gate electrode 20.

Since the injecting of n-type impurities into the base region 12A covered with the mask 91 is shielded, the conductivity type of the base region 12A at this portion maintains the p-type.

Since the gate electrode 20 is a conductive layer made of a polysilicon having conductivity, the conductivity is not affected even when the n-type impurities are injected thereinto.

Then, as illustrated in FIG. 4B, the interlayer insulating film 30 which covers the gate electrode 20, the source region 13, and the mask 91 is formed.

Then, as illustrated in FIG. 4C, a part of the gate insulating film 21, the interlayer insulating film 30, and the mask 91 are removed to expose the surface of the base region 12A and the surface of the source region 13. The removal thereof is done by, for example, chemical mechanical polishing (CMP). Alternatively, dry etching may be performed to remove a part of the gate insulating film 21, the interlayer insulating film 30, and the mask 91.

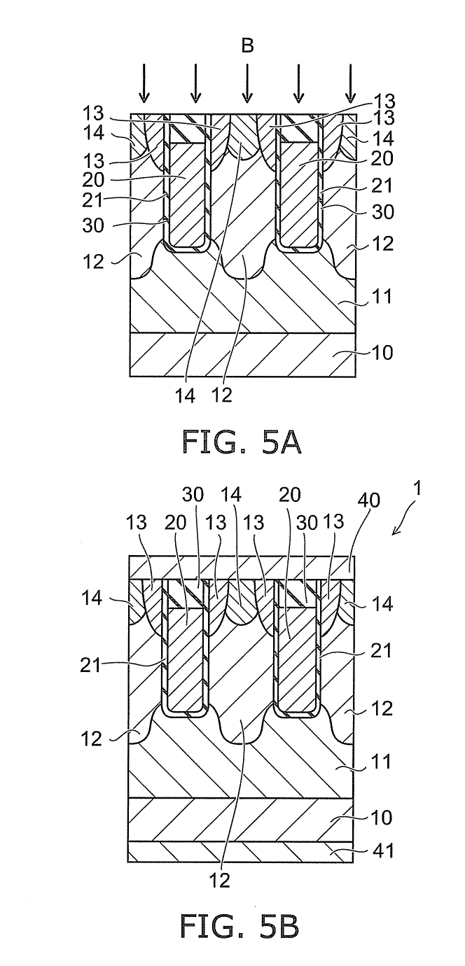

FIGS. 5A and 5B are schematic cross-sectional views explaining the manufacturing process of the semiconductor device according to the first embodiment. FIG. 5A illustrates a schematic cross-sectional view in the process for forming the contact region, and FIG. 5B illustrates a schematic cross-sectional view the process for forming the source electrode and the drain electrode.

As illustrated in FIG. 5A, second conductivity type (p-type) impurities are injected into the base region 12A at portions other than the portion of formed source region 13. For example, p-type impurities such as boron (B) are injected into the source region 13 and into the exposed surface of the base region 12A at portions other than the portion of formed source region 13. The direction of injecting the p-type impurities is almost normal to the major surface of the semiconductor substrate 10.

During the operation, no mask for ion-implantation is provided on the base region 12A and on the source region 13. Furthermore, the p-type impurities are injected into the base region 12A at portions other than the portion of formed source region 13 to the extent that the conductivity type of the source region 13 is not inversed. Since the base region 12A which is sandwiched between the source regions 13 contains the p-type impurities, the concentration of the p-type impurities in the region becomes higher than those in the base region 12A.

By the operation, on the surface of the base region 12A, there is formed selectively the p⁺-type contact region 14 having higher concentration of impurities than those in the base region 12A. The contact region 14 is selectively formed on the surface of the base region 12A so as to be sandwiched between the source regions 13 and so as to be adjacent to the source region 13. The contact region 14 is formed on the surface of the base region 12A containing no n-type impurities. As a result, the contact region 14 does not need to dope the p-type impurities to the extent that the formed n-type conductivity is negated. The semiconductor region of the base region 12A excluding the source region 13 and the contact region 14 becomes the base region 12.

Next, as illustrated in FIG. 5B, the source electrode 40 is formed on the source region 13, the contact region 14, and the interlayer insulating film 30. By the operation, there is formed the source electrode 40 which electrically connects to the source region 13 and the contact region 14. The drain electrode 41 is formed beneath the semiconductor substrate 10. By the operation, there is formed the drain electrode 41 conducting with the semiconductor substrate 10. By the above manufacturing process, the semiconductor device 1 is fabricated.

The description about the effect of the method of manufacturing the semiconductor device 1 will be given below.

Before describing the effect of the method of manufacturing the semiconductor device 1, the description will be given to semiconductor devices 100 and 200 in comparative examples. In the semiconductor devices 100 and 200, the same member as that of the semiconductor device 1 has the same reference numeral.

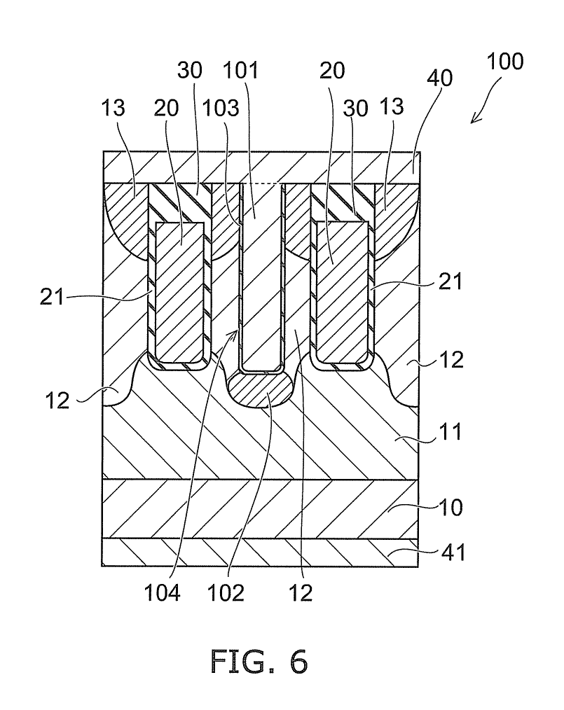

FIG. 6 is a schematic cross-sectional view of the semiconductor device according to a first comparative example.

The semiconductor device 100 according to the first comparative example is a vertical trench-gate type MOSFET.

In the semiconductor device 100, the source region 13 is selectively provided on the surface of the base region 12. In the base region 12, a trench-shape contact region 101 is provided in addition to the source region 13. The contact region 101 is connected to the source electrode 40. The material of the contact region 101 is, for example, a conductive metal. A barrier layer 103 is provided around the contact region 101. The presence of the barrier layer 103 prevents the component of the contact region 101 from diffusing into the base region 12 and the source region 13. The lower end of the contact region 101 is joined to a p-type layer 102. The concentration of the p-type impurities in the p-type layer 102 is higher than those in the base region 12.

According to the semiconductor device 100, the hole generated by avalanche breakdown can be discharged to the source electrode 40 via the p-type layer 102 and the contact region 101. Consequently, the semiconductor device 100 has a high avalanche breakdown voltage.

Since, however, the semiconductor device 100 forms the contact region 101 having a high aspect ratio in the base region 12, the process for forming the contact region 101 becomes complex.

For example, the process for forming the contact region 101 proceeds as follows:

(1) first, forming a trench 104 having a high aspect ratio in the base region 12 to form the contact region 101;
(2) then, forming the barrier layer 103 on inside wall of the trench 104;
(3) and then burying a conductive metal that is the material of contact region 101, in the trench 104. Furthermore, before forming the trench 104, it is necessary to form a mask which opens the region of trench 104 on the base region 12, in advance, by photolithography.

Therefore, for the semiconductor device 100, the process for forming the contact region 101 becomes complicated.

In addition, the barrier layer 103 with a uniform thickness cannot always be formed on inside wall of the trench 104 having a high aspect ratio. In particular, at a portion having a thin barrier layer 103, the barrier properties become weak, which may result in diffusing the metal component of the contact region 101 into the base region 12 and the source region 13, in some cases.

Furthermore, the contact region 101 itself becomes an impediment and thus the reduction in the cell pitch becomes difficult.

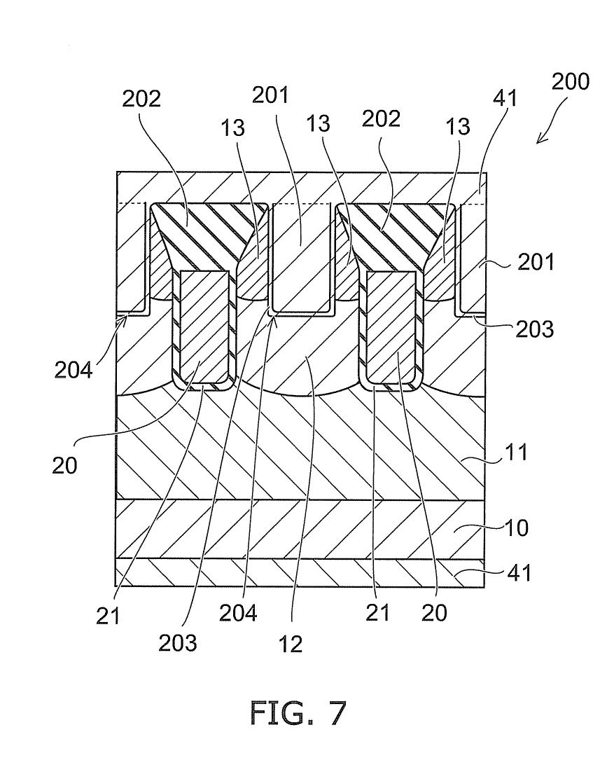

FIG. 7 is a schematic cross-sectional view of the semiconductor device according to a second comparative example.

In the semiconductor device 200, the source region 13 is selectively provided on the surface of the base region 12. On the base region 12, there is provided a trench-shape contact region (a trench-contact layer) 201, other than the source region 13. The contact region 201 penetrates the source region 13, and the lower end thereof reaches the base region 12.

The contact region 201 is connected to the source electrode 40. The material of the contact region 201 is, for example, a conductive metal. A barrier layer 203 is formed around the contact region 201. The presence of the barrier layer 203 prevents the component of the contact region 201 from diffusing into the base region 12 and the source region 13. An interlayer insulating film 202 having a cross section of reverse-trapezoidal shape is provided on the contact region 201.

The process for forming the contact region 201 in that type of semiconductor device 200 proceeds as follows:

(1) first, forming the source region 13 on the surface of the base region 12, followed by forming a trench 204 having a high aspect ratio in the base region 12 by using the interlayer insulating film 202 as the mask, causing the trench 204 to penetrate through the source region 13, and causing the lower end thereof to reach the base region 12;
(2) next, forming the barrier layer 203 on inside wall of the trench;
(3) and then, burying a conductive metal as the material of the contact region 201 in the trench.

Since the above process forms the trench 204 by using the interlayer insulating film 202 formed on the gate electrode 20 as the mask, there is no need of forming a dedicated mask for forming the trench 204 by photolithography. Consequently, there is no need of aligning the position of the dedicated mask with that of the gate electrode 20 (or the trench 204).

In the semiconductor device 200, however, the width of the source region 13 becomes significantly narrow because the trench 204 is formed by penetrating through the source region 13. Therefore, after the process of (1) to (3), it becomes difficult to form the contact region that is the hole-free region, adjacent to the source region 13.

In addition, the barrier layer 203 with a uniform thickness cannot always be formed on inside wall of the trench 204 having a high aspect ratio. In particular, at a portion having weak barrier properties, the metallic component of the contact region 201 may diffuse in the base region 12 and the source region 13 in some cases.

Furthermore, the contact region 201 itself becomes an impediment and thus the reduction in the cell pitch becomes difficult.

In contrast to this, in the method of manufacturing the semiconductor device 1, the trench-shape contact regions 101 and 201 are not provided, and thus the manufacturing process is simplified, which can reduce the manufacturing cost. Furthermore, since there is no need of providing the contact regions 101 and 201, the metallic component of the contact regions 101 and 201 does not diffuse into the base region 12 and the source region 13. In addition, the absence of the contact regions 101 and 201 can achieve the narrowing of the pitch.

According to the method of manufacturing the semiconductor device 1, the source region 13 and the contact region 14 that is the layer free of carrier are formed in self-aligning mode.

The term “self-aligning mode” referred to herein means that, in the case of forming the source region 13 and the contact region 14 by ion-implantation method, there is no need of aligning the position of the mask for shielding the ion beam with that of the gate electrode 20 (or the trench 92).

In other words, according to the process of manufacturing the semiconductor device 1, there is not included the process of newly forming the dedicated mask which opens only the source region 13 by photolithography, and of forming the source region 13 by ion implantation through the use of the dedicated mask. Similarly, there is not included the process of newly forming the dedicated mask which opens only the contact region 14 by photolithography, and of forming the contact region 14 by ion implantation through the use of the dedicated mask.

In contrast to this, when the respective dedicated masks which opens only the source region 13 are formed on the base region 12A using photolithography, a position displacement occurs in aligning the position of the dedicated mask with that of the gate electrode 20. Similarly, when the respective dedicated masks which open only the contact region 14 are formed on the base region 12A by using photolithography, a position displacement occurs in aligning the position of the dedicated mask with that of the gate electrode 20.

Therefore, when the dedicated mask which opens the source region 13 or the contact region 14 is formed on the base region 12A, the size corresponding to the position displacement has to be taken into account in advance, and the size has to be added to each of the source region 13 and the contact region 14 before executing the photolithography process. As a result, the length corresponding to the position displacement is added to the width of the source region 13 or to the width of the contact region 14, which makes the reduction in the cell pitch difficult.

In contrast to this, according to the method of manufacturing the semiconductor device 1, the mask 91 for forming the trench 92 is formed, followed by simply enlarging the opening width of the mask 91, and the mask 91 is used as the mask when forming the source region 13. As a result, there is no need of newly forming the dedicated mask for forming the source region 13 by photolithography. Consequently, when the source region 13 is formed, aligning the position of the mask 91 with that of the gate electrode 20 (or the trench 92) is not needed. Accordingly, the source region 13 becomes difficult to be displaced with respect to the gate electrode 20.

Furthermore, also the contact region 14 is formed by self-aligning without using the mask. Consequently, there is no need of forming the dedicated mask for forming the contact region 14 by photolithography. In particular, in forming the contact region 14, the injection of the p-type impurities into the exposed surfaces of the base region 12A, the source region 13, and the interlayer insulating film 30 is enough.

As described above, according to the method of manufacturing the semiconductor device 1, there is no need of taking into account the position displacement of the mask in the process of forming the source region 13 and the contact region 14. As a result, the length of position displacement is not added to the width of the source region 13 and the width of the contact region 14, respectively. Consequently, the method of manufacturing the semiconductor device 1 can reduce the cell pitch.

Furthermore, according to the method of manufacturing the semiconductor device 1, since the source region 13 and the contact region 14 are formed by self-aligning, the above-described process can be applied without modification even when the pitch of the semiconductor device 1 is designed to be further narrower.

Furthermore, as the pitch in the semiconductor device 1 becomes narrower, the channel density of the semiconductor device 1 increases, and thus the ON-resistance of the semiconductor device can be further lowered.

In addition, since the contact region 14 is formed in the base region 12A inherently containing p-type impurities, the contact region 14 does not need the injecting of the p-type impurities so as to negate the existing n-type conductivity. Therefore, the p-type impurities in the contact region 14 diffuses very little to the base region 12 and the source region 13, and thus the presence of the contact region 14 does not affect the threshold voltage of the semiconductor device 1 and does not adversely affect the conductivity of the source region 13.

As described above, according to the method of manufacturing the semiconductor device 1, the increase in the manufacturing cost is suppressed, the cell pitch of MOS transistor in the semiconductor device 1 is further decreased, and the semiconductor device 1 having a further high resistance to avalanche breakdown can be formed.

The following will be the description of modified examples of the semiconductor device 1. In the following description, the same member as that in the semiconductor device 1 has the same reference numeral as that in the semiconductor device 1, and detail description for the member may not be given.

### Second Embodiment

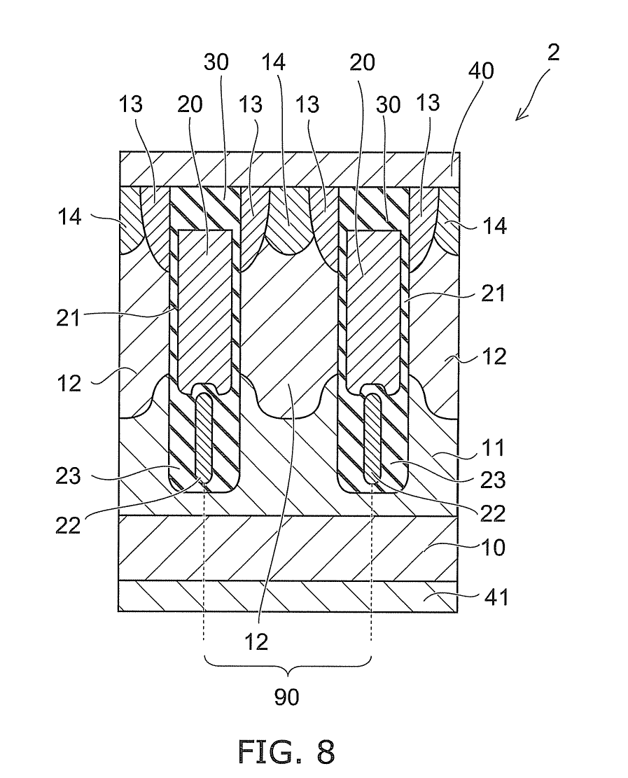

FIG. 8 is a schematic cross-sectional view of the semiconductor device according to a second embodiment.

The semiconductor device 2 illustrated in FIG. 8 is a vertical trench-gate type MOSFET.

The semiconductor device 2 has a field-plate structure in addition to the basic structure of the semiconductor device 1. For example, the semiconductor device 2 includes a field-plate electrode 22 below the trench-shape gate electrode 20. The field-plate electrode 22 is connected electrically to, for example, the source electrode 40 (or the source region 13), or the gate electrode 20. The material of the field-plate electrode 22 is, for example, a polysilicon. A field-plate insulating film (a second insulating film) 23 is interposed between the field-plate electrode 22 and the semiconductor layer 11. The thickness of the field-plate insulating film 23 is designed to be larger than the thickness of the gate insulating film 21. The material of the field-plate insulating film 23 is, for example, silicon oxide (SiO₂).

The basic operation of the semiconductor device 2 is the same as that of the semiconductor device 1. When, however, a ground potential is applied to the source electrode 40 of the semiconductor device 2, and when a positive potential is applied to the drain electrode 41 thereof, the depleted layer spreads out from the interface between the base region 12 and the semiconductor layer 11, and the depleted layer also spreads out from the interface between the semiconductor layer 11 and the field-plate insulating film 23 facing the field-plate electrode 22.

In the semiconductor device 2, the depleted layer in the semiconductor layer 11 becomes easier to spread than that in the semiconductor device 1 by the presence of the field-plate insulating film 23. Accordingly, the concentration of impurities in the semiconductor layer 11 of the semiconductor device 2 can be set to be higher than the concentration of impurities in the semiconductor layer 11 of the semiconductor device 1. As a result, the electric resistance of the semiconductor layer 11 further decreases, and the ON-resistance of the semiconductor device 2 decreases more than the ON-resistance of the semiconductor device 1.

Next will be the description about the process of manufacturing the semiconductor device 2. The manufacturing process of FIGS. 2A to 2C can be applied to the manufacturing process for the semiconductor device 2. The description will begin from the succeeding process to FIG. 2C.

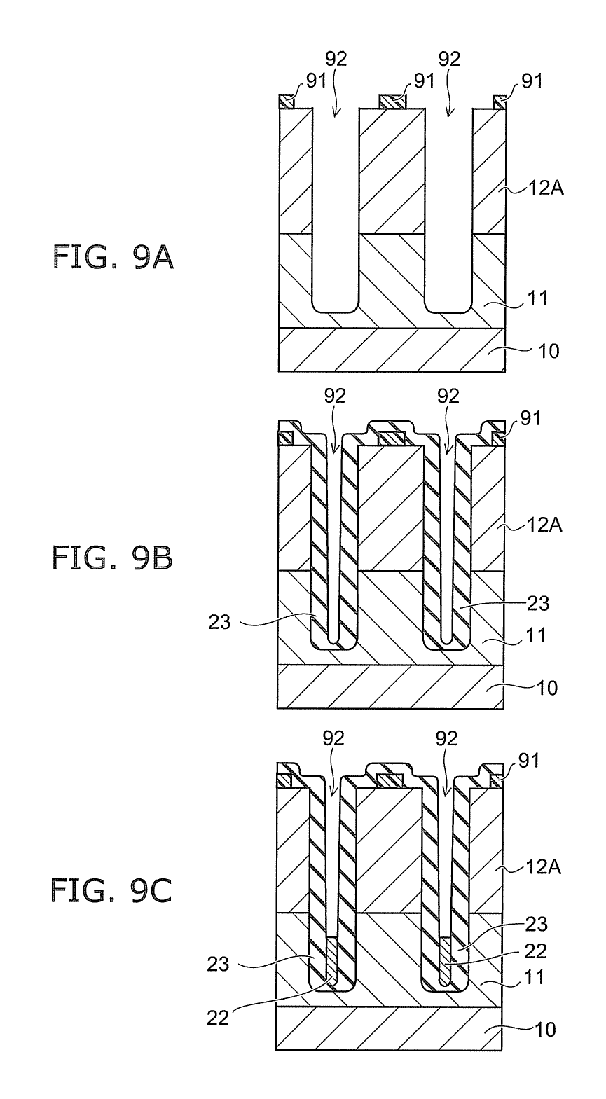

FIGS. 9A to 9C are schematic cross-sectional views describing a manufacturing process of the semiconductor device according to the second embodiment. FIG. 9A illustrates a schematic cross-sectional view for enlarging the mask opening, FIG. 9B illustrates a schematic cross-sectional view in the process for forming the field-plate insulating film, and FIG. 9C illustrates a schematic cross-sectional view in the process for forming the field-plate electrode.

As illustrated in FIG. 9A, after forming the trench 92, side-etching is applied to the mask 91 which has been formed on the base region 12A. The side-etching is, for example, isotropic etching (wet etching). The side-etching removes the side surfaces of the mask 91. As a result, the opening width of the mask 91 is further enlarged compared with the opening width of the mask 91 before forming the trench 92. The adjustment of the opening width of the mask 91 is carried out by, for example, controlling the time of isotropic etching. In the manufacturing process of the semiconductor device 2, the trench 92 is formed deeper than the trench 92 illustrated in FIG. 2C.

Next, as illustrated in FIG. 9B, the field-plate insulating film 23 is formed on inside wall of the trench 92. The field-plate insulating film 23 is formed on inside wall of the trench 92 by, for example, a thermal oxidation method or a CVD method.

Then, as illustrated in FIG. 9C, the field-plate electrode 22 is formed in the trench 92 by, for example, a CVD method. With respect to the field-plate electrode 22, the upper surface thereof is adjusted so that the upper end of the field-plate electrode 22 becomes lower than the lower end of the gate electrode 20 which is formed in succeeding process. The height of the upper surface of the field-plate electrode 22 is adjusted by, for example, an etch-back method.

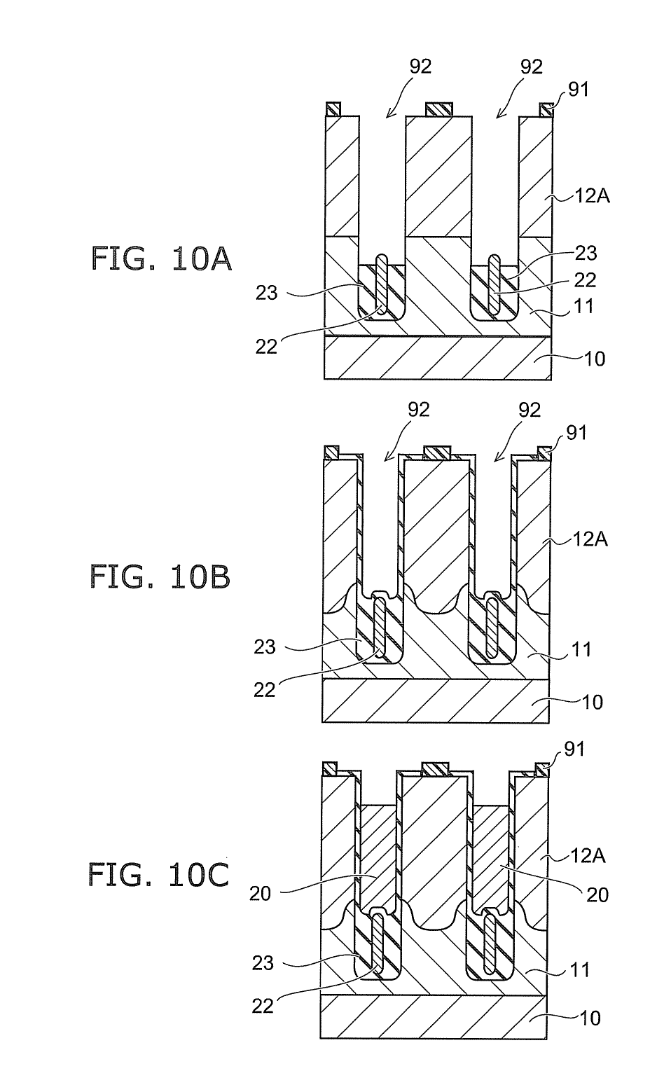

FIGS. 10A to 10C are schematic cross-sectional views explaining the manufacturing process of the semiconductor device according to the second embodiment. FIG. 10A illustrates a schematic cross-sectional view explaining the process for etching the field-plate insulating film, FIG. 10B illustrates a schematic cross-sectional view in the process for forming the gate insulating film, and FIG. 10C illustrates a schematic cross-sectional view in the process for forming the gate electrode.

Next, as illustrated in FIG. 10A, the field-plate insulating film 23 is subjected to etching. The etching is, for example, isotropic etching (wet etching). The etching causes the upper end of the field-plate electrode 22 to protrude from the field-plate insulating film 23. At this moment, the field-plate insulating film 23 contact with the field-plate electrode 22 remains because the etchant of the field-plate insulating film 23 does not fully enter.

Then, as illustrated in FIG. 10B, the gate insulating film 21 is formed on inside wall of the trench 92 and on the field-plate electrode 22. For example, the semiconductor layer 11 and the base region 12A are heated in an atmosphere of oxidizing gas such as oxygen (O₂) to form the gate insulating film 21 on inside wall of the trench 92 by a thermal oxidation. Furthermore, the heating causes the impurities in the base region 12A to diffuse toward the semiconductor layer 11, and thus a part of the boundary between the semiconductor layer 11 and the base region 12A moves toward the semiconductor substrate 10.

Regarding the gate insulating film 21, forming thereof by a CVD method, other than by a thermal oxidation method, is also included in the second embodiment.

Then, as illustrated in FIG. 10C, the gate electrode 20 is formed in the trench 92 by, for example, a CVD method. For the gate electrode 20, the height of the upper surface thereof is adjusted so that the upper end of the gate electrode 20 becomes higher than the lower end of the source region 13. The height of upper surface of the gate electrode 20 is adjusted by, for example, a etch-back method.

After that, as illustrated in FIG. 4A, the mask 91 is used as the shielding film to form selectively the source region 13 on the surface of the base region 12A. Then, as illustrated in FIG. 4B, the interlayer insulating film 30 is formed. Furthermore, as illustrated in FIG. 4C, the interlayer insulating film 30 and the mask 91 are polished. Then, as illustrated in FIG. 5A, the contact region 14 is formed. The base region 12 is formed in a semiconductor region of the base region 12A excluding the source region 13 and the contact region 14. Furthermore, as illustrated in FIG. 5B, the source electrode 40 and the drain electrode 41 are formed. Through the manufacturing process, the semiconductor device 2 is fabricated.

The effect of the method of manufacturing the semiconductor device 2 is similar to that of manufacturing the semiconductor device 1.

### Third Embodiment

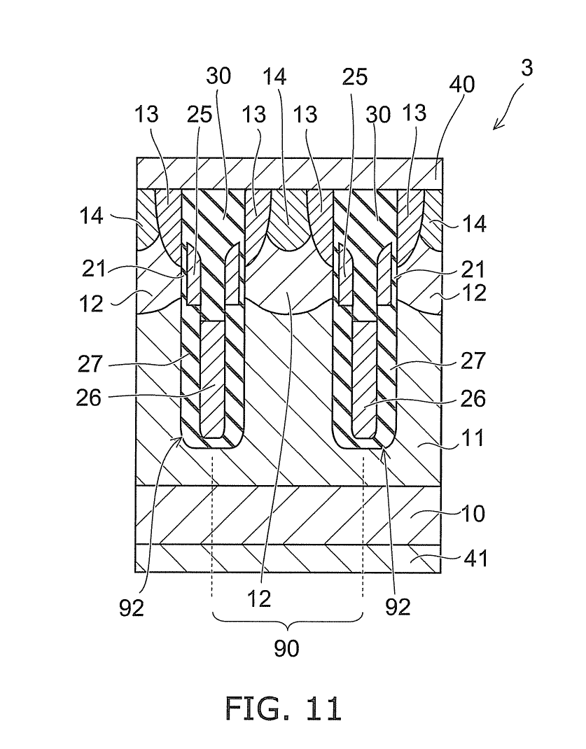

FIG. 11 is a schematic cross-sectional view of the semiconductor device according to a third embodiment.

A semiconductor device 3 illustrated in FIG. 11 is a vertical trench-gate type MOSFET.

In the semiconductor device 3, gate electrodes 25 are positioned in the trench 92 so as to face each other. At least a part of the plane of the respective gate electrodes 25 facing each other has a curved surface. Other than in the curved surface, the plane of the respective gate electrodes 25 facing each other may be almost parallel to each other, or be inclined.

The interlayer insulating film 30 is provided on the gate electrode 25. The interlayer insulating film 30 extends into a region between the gate electrodes 25 facing each other. A field-plate electrode 26 is disposed beneath the extended interlayer insulating film 30. A field-plate insulating film 27 is interposed between the field-plate electrode 26 and the semiconductor layer 11. The interlayer insulating film 30 and the field-plate insulating film 27 are interposed between the gate electrode 25 and the field-plate electrode 26.

The upper end of the field-plate electrode 26 is lower than the upper end of the field-plate insulating film 27. The thickness of the field-plate insulating film 27 is larger than that of the gate insulating film 21. The gate electrode 25 is disposed on the field-plate insulating film 27.

The field-plate electrode 26 is electrically connected to, for example, the source electrode 40 (or the source region 13) or the gate electrode 25. The material of the field-plate electrode 26 is, for example, a polysilicon. The material of the field-plate insulating film 27 is, for example, silicon oxide (SiO₂).

When a ground potential is applied to the source electrode 40 of the semiconductor device 3, and when a positive potential is applied to the drain electrode 41 thereof, the depleted layer spreads from the interface between the base region 12 and the semiconductor layer 11, and also the depleted layer spreads from the interface between the semiconductor layer 11 and the field-plate insulating film 27 facing the field-plate electrode 26.

When a certain voltage is applied between the source electrode 40 and the drain electrode 41 in that type of semiconductor device 3 (for example, ground potential to the source electrode 40, and a positive potential to the drain electrode 41), and when a voltage higher than the threshold voltage is applied to the gate electrode 25, a channel (an inversion layer) is formed in the base region 12 facing the gate electrode 25 via the gate insulating film 21. And then, a current flows between the source electrode 40 and the drain electrode 41 through the source region 13, the channel, the semiconductor layer 11, and the semiconductor substrate 10. That is, the semiconductor device 3 enters ON state. When the voltage of the gate electrode 25 becomes lower than the threshold voltage, no channel is formed in the base region 12, and no current flows between the source electrode 40 and the drain electrode 41. That is, the semiconductor device 3 enters OFF state.

When the semiconductor device 3 is in ON state, electronic current flows between the source region 13 and the semiconductor layer 11 via the channel. Consequently, the potential difference between the source region 13 and the semiconductor layer 11 becomes extremely small. In contrast, when the semiconductor device 3 is switched from ON state to OFF state, the potential difference between the source region 13 and the semiconductor layer 11 abruptly increases, and temporarily exceeds the potential difference in the OFF state, resulting in an over-voltage state.

At this moment, there is generated avalanche breakdown at the joint interface of the base region 12 and the semiconductor layer 11, which generates electron-hole pair in some cases.

When holes are accumulated in the semiconductor device 3, the avalanche breakdown is further accelerated and thus the breakdown of the semiconductor device 3 is caused in some cases. In the semiconductor device 3, however, the holes generated migrate in the base region 12 toward the source electrode 40, and is efficiently discharged to the source electrode 40 via the contact region 14 which is a carrier-free region. As a result, the semiconductor device 3 assures high resistance to avalanche breakdown.

In the semiconductor device 3, the depleted layer in the semiconductor layer 11 becomes easily spread compared with that in the semiconductor device 1 by the presence of the field-plate electrode 26. Consequently, the concentration of impurities in the semiconductor layer 11 of the semiconductor device 3 can be set to be higher than those in the semiconductor layer 11 of the semiconductor device 1. As a result, the electric resistance of the semiconductor layer 11 further decreases, and the ON-resistance of the semiconductor device 3 decreases more than the ON-resistance of the semiconductor device 1.

Next will be the description about the process of manufacturing the semiconductor device 3. The manufacturing process of FIGS. 2A to 2C can be applied to that for the semiconductor device 3. The description will begin with the succeeding process to FIG. 2C.

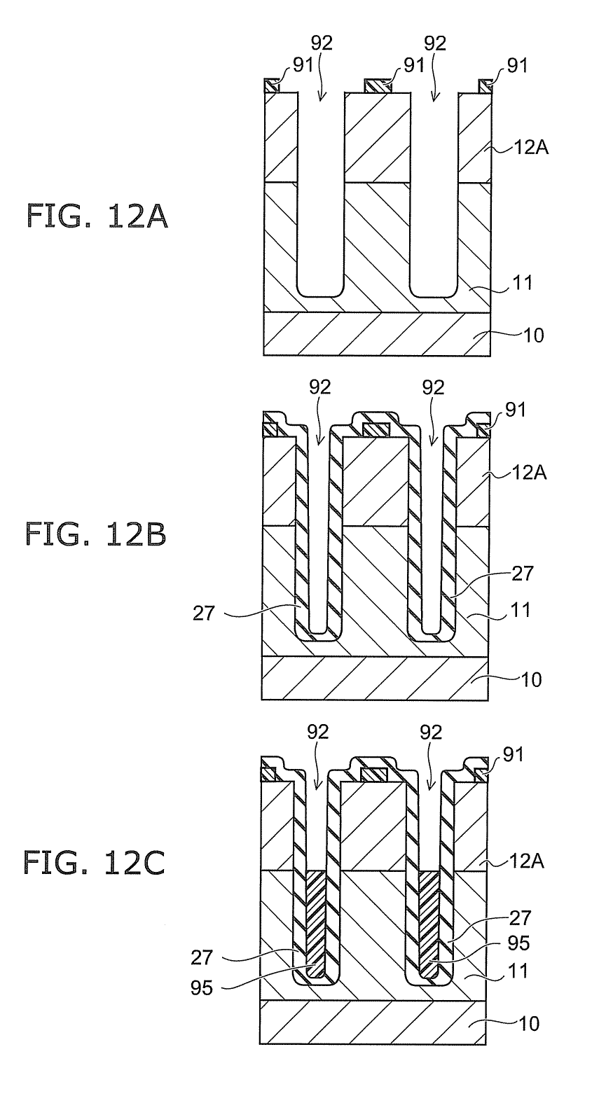

FIGS. 12A to 12C are schematic cross-sectional views explaining the manufacturing process of the semiconductor device according to the third embodiment. FIG. 12A illustrates a schematic cross-sectional view describing the process for enlarging the mask opening, FIG. 12B illustrates a schematic cross-sectional view in the process for forming the field-plate insulating film, and FIG. 12C illustrates a schematic cross-sectional view in the process for forming the resist layer.

As illustrated in FIG. 12A, after forming the trench 92, the mask 91 formed on the base region 12A is subjected to side-etching. The side-etching is, for example, isotropic etching (wet etching). The side-etching removes the side surfaces of the mask 91. As a result, the opening width of the mask 91 is further enlarged from the opening width of the mask 91 before forming the trench 92. Adjustment of the opening width of the mask 91 is carried out by, for example, controlling the time of isotropic etching. Meanwhile, in the manufacturing process of the semiconductor device 3, the depth of the trench 92 is deeper than that of the trench 92 illustrated in FIG. 2C.

Next, as illustrated in FIG. 12B, the field-plate insulating film 27 is formed on inside wall of the trench 92. For example, by using a thermal oxidation method or a CVD method, the field-plate insulating film 27 is formed on inside wall of the trench 92.

Then, as illustrated in FIG. 12C, a resist layer 95 is formed at lower part of the trench 92 via the field-plate insulating film 27. Adjustment of the height of upper surface of the resist layer 95 is carried out by, for example, etch-back which utilizes ashing processing or the like.

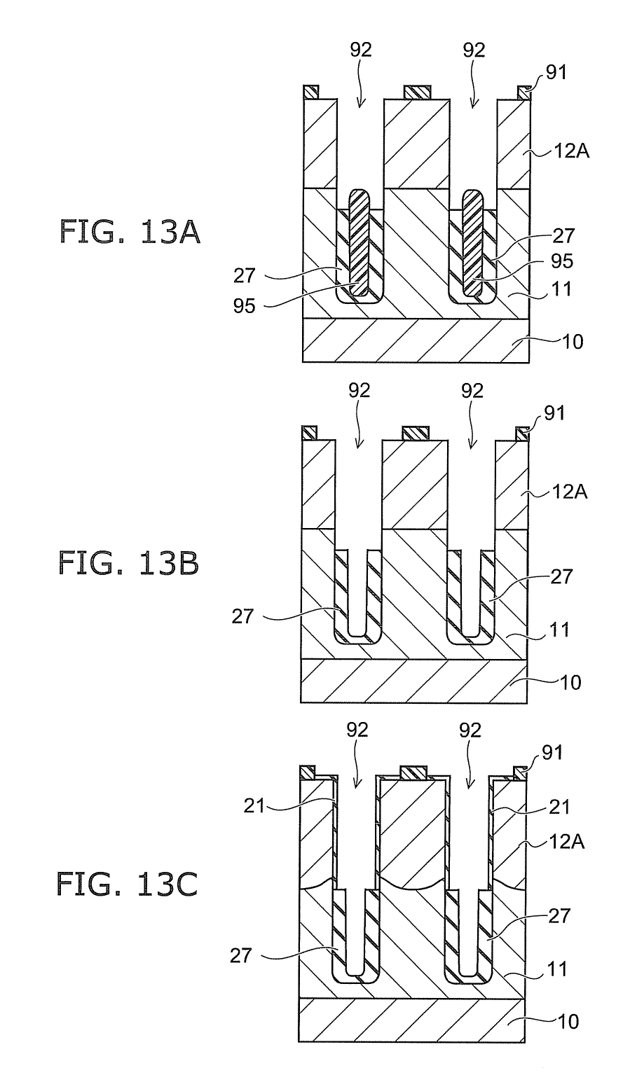

FIGS. 13A to 13C are schematic cross-sectional views describing the manufacturing process of the semiconductor device according to the third embodiment. FIG. 13A illustrates a schematic cross-sectional view describing the process for etching of the field-plate insulating film, FIG. 13B illustrates a schematic cross-sectional view in the process for removing the resist, and FIG. 13C illustrates a schematic cross-sectional view in the process for forming the gate insulating film.

As illustrated in FIG. 13A, the field-plate insulating film 27 is subjected to etching. The etching is, for example, isotropic etching (wet etching). The etching causes the upper end of the resist layer 95 to protrude from the field-plate insulating film 27. At this moment, the field-plate insulating film 27 in contact with the resist layer 95 remains because the etchant of the field-plate insulating film 27 does not fully enter.

Next, as illustrated in FIG. 13B, the resist layer 95 is removed by using ashing processing or by using an organic solvent.

Then, as illustrated in FIG. 13C, the gate insulating film 21 is formed on inside wall of the trench 92. For example, the semiconductor layer 11 and the base region 12A are heated in an atmosphere of oxidizing gas such as oxygen (O₂) to form the gate insulating film 21 on inside wall of the trench 92 by a thermal oxidation.

By the operation, there are formed the field-plate insulating film 27 contact with to the field-plate electrode 26, and the gate insulating film 21 having a smaller thickness than that of the field-plate insulating film 27 and being in contact with the gate electrode 25, on inside wall of the trench 92. The heating causes the impurities in the base region 12A to diffuse toward the semiconductor layer 11, and causes a part of the boundary between the semiconductor layer 11 and the base region 12A to move toward the semiconductor substrate 10.

Regarding the gate insulating film 21, forming thereof by a CVD method, other than by a thermal oxidation method, is included in the third embodiment.

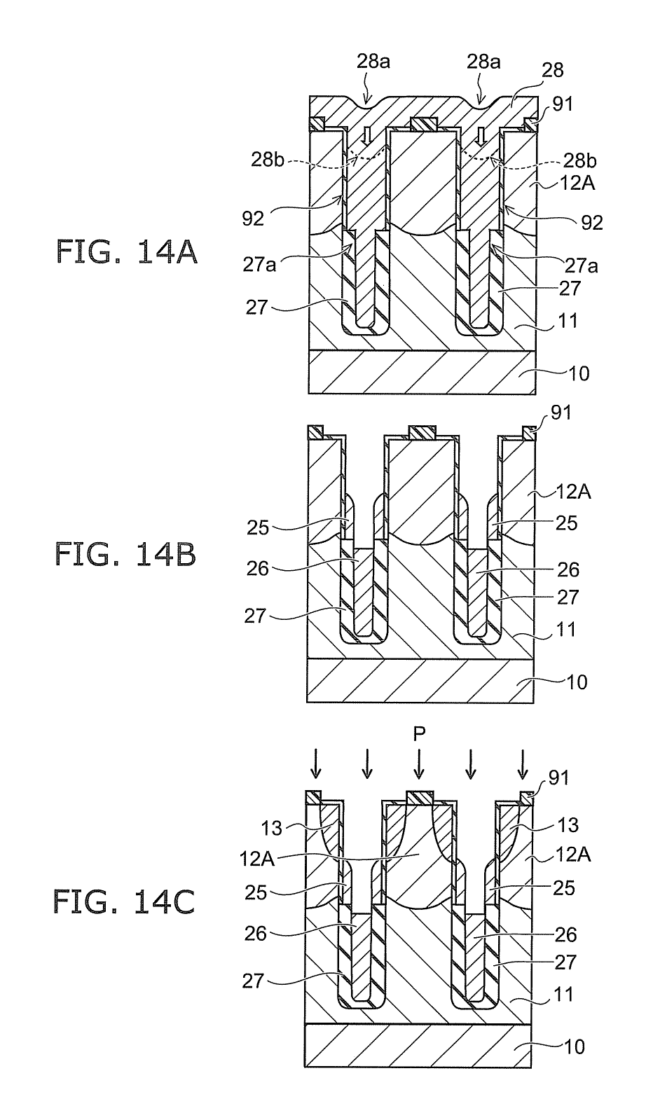

FIGS. 14A to 14C are schematic cross-sectional views describing the manufacturing process of the semiconductor device according to the third embodiment. FIG. 14A illustrates a schematic cross-sectional view in the process for forming the conductive layer, FIG. 14B illustrates a schematic cross-sectional view in the process for forming the gate electrode and the field-plate electrode, and FIG. 14C illustrates a schematic cross-sectional view in the process for forming the source region.

As illustrated in FIG. 14A, a conductive layer 28 made up of a polysilicon is formed in the trench 92 by using, for example, a CVD method. The conductive layer 28 is also buried between the field-plate insulating films 27. Since the conductive layer 28 is buried in the trench 28 by using the CVD method which has excellent step-covering performance, a concave 28a is formed at center part of the conductive layer 28. The film thickness (the layer thickness) of the conductive layer 28 in contact with the field-plate insulating film 27 is adjusted so as to be half or more the width of the trench 92. The film thickness (the layer thickness) of the conductive layer 28 in contact with the gate insulating film 21 is adjusted so as to be half or more the width of the trench 92.

Next, the conductive layer 28 is subjected to anisotropic etching. The anisotropic etching deepens an etching surface 28b along the surface of the concave 28a. The etching surface 28b then reaches an end 27a of the field-plate insulating film 27.

Thus, in the trench 92, the conductive layer 28 is divided into the gate electrode 25 in contact with the gate insulating film 21 and the field-plate electrode 26 in contact with the field-plate insulating film 27. This state is illustrated in FIG. 14B.

As illustrated in FIG. 14B, there are formed the gate electrode 25 and the field-plate electrode 26. For example, in the trench 92, there is formed the field-plate electrode 26 electrically connecting to the source region 13 or the gate electrode 25, below the gate electrode 25.

Then, as illustrated in FIG. 14C, n-type impurities such as phosphorus (P) are injected into the exposed surface of the base region 12A, the gate electrode 25, and the field-plate electrode 26 in a direction almost normal to the major surface of the semiconductor substrate 10. In this operation, the n-type impurities are not injected into the base region 12A covered with the mask 91, and is injected into the base region 12A exposed from the mask 91. The condition of ion implantation is adjusted to the extent that the n-type impurities pass through the gate insulating film 21 formed on the base region 12A. Furthermore, into the surface of the base region 12A exposed from the mask 91, the n-type impurities are injected to the extent that the conductivity type of the base region 12A is inversed. By the operation, the n-type source region 13 is selectively formed in a portion ranging from the upper end of the base region 12A to the midstream of the gate electrode 25.

Since the dosing of n-type impurities into the base region 12A covered with the mask 91 is shielded, the conductivity type of the base region 12A in this portion maintains the p-type.

Since the gate electrode 25 and the field-plate electrode 26 are polysilicon layers having conductivity, respectively, the conductivity is not affected even when the n-type impurities are injected thereinto.

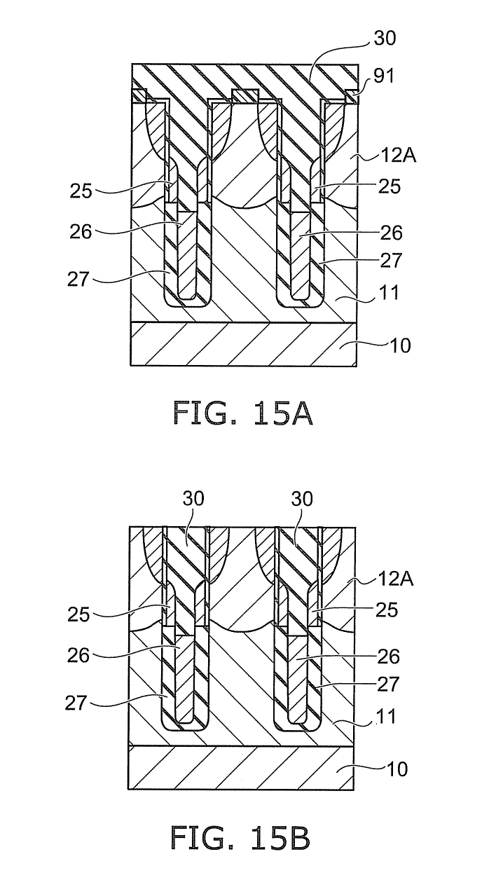

FIGS. 15A and 15B are schematic cross-sectional views describing the manufacturing process of the semiconductor device according to the third embodiment. FIG. 15A illustrates a schematic cross-sectional view in the process for forming the interlayer insulating film, and FIG. 15B illustrates a schematic cross-sectional view in the process for removing the interlayer insulating film and the mask.

As illustrated in FIG. 15A, there is formed the interlayer insulating film 30 covering the gate electrode 25, the field-plate electrode 26, the source region 13, and the mask 91.

Then, as illustrated in FIG. 15B, the gate insulating film 21 in a part thereof, the interlayer insulating film 30, and the mask 91 are removed by grinding to thereby expose the surface of the base region 12A and the surface of the source region 13.

After that, as illustrated in FIG. 15A, the contact region 14 is formed. The base region 12 is formed in a portion where the source region 13 and the contact region 14 are removed from the base region 12A. Furthermore, as illustrated in FIG. 15B, the source electrode 40 and the drain electrode 41 are formed. Through the above process, the semiconductor device 3 is fabricated.

The description about the effect of the semiconductor device 3 and the effect of the method of manufacturing the semiconductor device 3 will be given below.

Before describing the effect of the semiconductor device 3 and the effect of the method of manufacturing the semiconductor device 3, the description will be given to a semiconductor device 300 according to comparative examples. In the semiconductor device 300, the same member as that of the semiconductor device 3 has the same reference numeral.

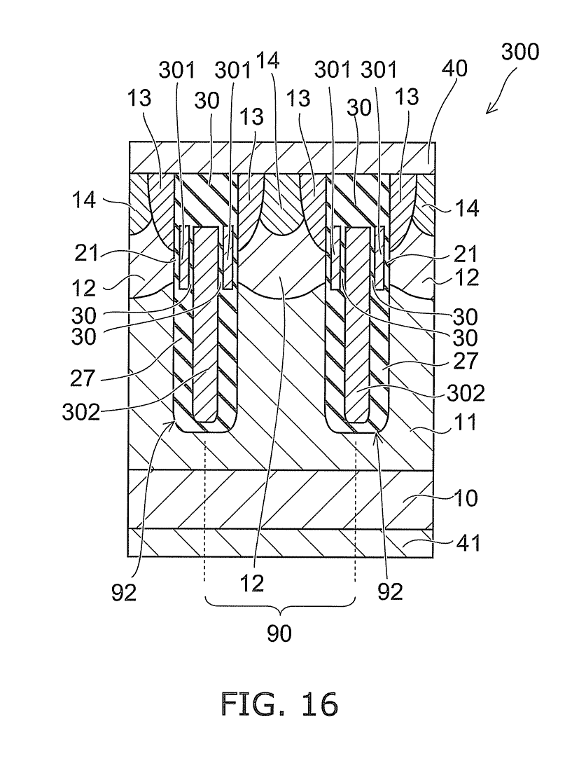

FIG. 16 is a schematic cross-sectional view of the semiconductor device according to a third comparative example.

In the semiconductor device 300, trench-shape gate electrodes 301 are disposed so as to face each other in the trench 92. A field-plate electrode 302 is provided between the gate electrodes 301 facing each other. The interlayer insulating film 30 is interposed between the gate electrode 301 and the field-plate electrode 302. That is, the major surface of the gate electrode 301 faces the major surface of the field-plate electrode 302 via the interlayer insulating film 30. The field-plate electrode 302 positioned between the gate electrodes 301 extends to the lower part of the trench 92. The field-plate electrode 302 is electrically connected to the source electrode 40 (or the source region 13) or the gate electrode 301.

With the above structure, there is formed a parallel and flat plate capacitor by the gate electrode 301, the interlayer insulating film 30, and the field-plate electrode 302. In particular, when the field-plate electrode 302 is electrically connected to the source electrode 40 (or the source region 13), the capacitance (Cgs) between the gate electrode 301 and the source electrode 40 increases, and the capacitance may adversely affect the switching properties of the semiconductor device 300 in some cases.

In contrast to this, in the semiconductor device 3, the gate electrode 25 and the field-plate electrode 26 do not face each other. Furthermore, there is provided the thick interlayer insulating film 30 or the field-plate insulating film 27 between the gate electrode 25 and the field-plate electrode 26. Consequently, Cgs of the semiconductor device 3 lowers compared with that of the semiconductor device 300. As a result, the semiconductor device 3 provides better switching properties.

In the manufacturing process of the semiconductor 3, the gate electrode 25 and the field-plate electrode 26 are not formed in separate processes. Instead, after forming the conductive layer 28, the conductive layer 28 is separated, and the gate electrode 25 and the field-plate electrode 26 are formed at a time. Therefore, the manufacturing cost does not increase.

The above embodiments have been described referring to examples. However, the embodiments are not limited to these examples. That is, changes and modifications of the design adequately performed by those skilled in the art are included in the embodiments as far as those changes and modifications have the characteristics of the embodiments. Furthermore, elements and their arrangement, material, condition, shape, size, and the like given in the above examples are not limited to those described ones, and can be changed and modified adequately without departing from the scope of the embodiments.

What is claimed is:

1. A method for manufacturing a semiconductor device, comprising:
forming a first semiconductor region of a second conductivity type on a semiconductor layer of a first conductivity type;
forming a mask selectively opening a surface of the first semiconductor region;
forming a trench penetrating through the first semiconductor region to reach the semiconductor layer by etching the first conductor region exposed at an opening of the mask;
further exposing a part of the surface of the first semiconductor region from the mask by enlarging the opening of the mask;
forming a control electrode in the trench via a first insulating film;
selectively forming a second semiconductor region of the first conductivity type on the surface of the first semiconductor region by selectively shielding the first semiconductor region through the mask and by injecting impurity of the first conductivity type into the part of the first semiconductor region;
removing the mask having the opening; and
selectively forming a third conductor region of the second conductivity type, having a higher concentration of impurity than a concentration of impurity in the first semiconductor region, on the surface of the first semiconductor region by injecting impurity of the second conductivity type into the first semiconductor region other than a portion in which the second semiconductor region is formed.

2. The method according to claim 1, wherein the opening of the mask is enlarged by applying etching to a side surface of the mask at a position of the opening of the mask.

3. The method according to claim 1, wherein a height of an upper surface of the control electrode is caused to be higher than a lower end of the second semiconductor region by etch-back treatment.

4. The method according to claim 1, wherein the first semiconductor region is selectively shielded by the mask with an enlarged opening, the impurity of the first conductivity type is injected into the control electrode and the part of the first semiconductor region, and the second semiconductor region is selectively formed on the surface of the first semiconductor region.

5. The method according to claim 1, wherein the impurity of the second conductivity type is injected into the second conductor region and into the first semiconductor region other than the portion in which second semiconductor region is formed, and the third semiconductor region is selectively formed on the surface of the first semiconductor region.

6. The method according to claim 1, wherein the impurity of the second conductivity type is injected into the first semiconductor region other than the portion in which second semiconductor region is formed so that the conductivity type in the second conductor region is not reversed.

7. The method according to claim 1, wherein a field-plate electrode electrically connected to the second semiconductor region or the control electrode is further formed beneath the control electrode in the trench.

8. The method according to claim 7, wherein the part of the surface of the first semiconductor region is further exposed from the mask, and a second insulating film having a thickness larger than a thickness of the first insulating film is formed in the trench before forming the first insulating film.

9. The method according to claim 8, wherein the field-plate electrode is formed in the trench via the second insulating film after forming the second insulating film.

10. The method according to claim 9, wherein a height of the upper end of the field-plate electrode is caused to be higher than the upper surface of the second insulating film by applying etching to the second insulating film after forming the field-plate electrode.

11. The method according to claim 10, wherein, after causing the upper end of the field-plate electrode to be higher than the upper surface of the second insulating film, the first insulating film is formed in the trench and on the field-plate electrode.

12. The method according to claim 11, wherein, after the forming the first insulating film, the control electrode is formed in the trench via the first insulating film.

13. The method according to claim 7, wherein, before the forming the control electrode and the field-plate electrode, a second insulating film being in contact with the field-plate electrode and the first insulating film having a smaller thickness than a thickness of the second insulating film and being in contact with the control electrode are formed on an inside wall of the trench.

14. The method according to claim 7, wherein, after enlarging the opening of the mask and after further exposing a part of the surface of the first semiconductor region from the mask, a second insulating film having a larger thickness than a thickness of the first insulating film is formed in the trench, and a resist layer is formed in the trench via the second insulating film.

15. The method according to claim 14, wherein, after forming the resist layer, an etching is applied to the second insulating film to cause an upper end of the resist layer to be higher than an upper surface of the second insulating film.

16. The method according to claim 15, wherein, after causing the upper end of the resist layer to be higher than the upper surface of the second insulating film, the resist layer is removed.

17. The method according to claim 16, wherein, after the removing the resist layer, the first insulating film is formed in the trench on an upper side of the second insulating film.

18. The method according to claim 17, wherein, after the forming the first insulating film and the second insulating film, a conductive layer is formed in the trench.

19. The method according to claim 18, wherein, after the forming the conductive layer, an exposed surface of the conductive layer is etched, and the conductive layer is divided into the control electrode and the field-plate electrode in the trench.

20. The method according to claim 19, wherein an etching is applied to the exposed surface of the conductive layer until the etching surface of the conductive layer reaches an upper end of the second insulating film.
